(19) United States
(12) Patent Application Publication
(10) Pub. No.: US 2025/0280659 A1
(43) Pub. Date: Sep. 4, 2025

(54) Display Apparatus

(71) Applicant: LG Display Co., Ltd., Seoul (KR)

(72) Inventor: Ji Yun Kim, Paju-si (KR)

(21) Appl. No.: 19/033,981

(22) Filed: Jan. 22, 2025

(30) Foreign Application Priority Data
Feb. 29, 2024 (KR) 10-2024-0029923

(51) Int. Cl. H10K 59/121; G09G 3/3233; H10K 59/122; H10K 59/126; H10K 59/40; H10K 59/80

(52) U.S. Cl. CPC H10K 59/1213; G09G 3/3233; H10K 59/122; H10K 59/126; H10K 59/40; H10K 59/873; G09G 2300/0426; G09G 2300/0819; G09G 2300/0842; G09G 2310/08

(57) ABSTRACT

A display apparatus includes a display panel in which a plurality of data lines, a plurality of gate lines, and a plurality of pixels are arranged, a gate driving circuit connected to the plurality of gate lines, and a data driving circuit connected to the plurality of data lines, wherein each pixel includes a light emitting element and a first transistor connected to the light emitting element, and a gate electrode of the first transistor and a second electrode of the first transistor do not overlap.

### CROSS-REFERENCE TO RELATED APPLICATION

This application claims the benefit of Republic of Korea Patent Application No. 10-2024-0029923 filed on Feb. 29, 2024, which is hereby incorporated by reference in its entirety.

### BACKGROUND

### Field of Technology

The present disclosure relates to a display apparatus.

### Discussion of the Related Art

A display apparatus for displaying various types information on a screen is a core technology of the information and communication era and is developing in the direction of being thinner, lighter, more portable, and having higher performance. Accordingly, display apparatuses that can be manufactured in a lightweight and thin form are in the spotlight.

Specific examples of display apparatuses include a liquid crystal display (LCD), a quantum dot (QD) display, a field emission display (FED), and an organic light emitting diode (OLED) display.

Among various display apparatuses, an OLED display, which is a self-luminous element, is advantageous in terms of power consumption due to low voltage operation and has a high response speed, high luminous efficacy, a wide viewing angle, and a high contrast ratio, and thus is being studied as a next-generation display.

### SUMMARY

There is a problem that the image quality of a display apparatus deteriorates when the display apparatus is driven at an extremely low grayscale.

Accordingly, the present disclosure is directed to a display apparatus that substantially obviates one or more problems due to limitations and disadvantages of the related art.

An object of the present disclosure is to provide a display apparatus capable of improving image quality at a low grayscale.

The object of the present disclosure is not limited to the object mentioned above, and other objects not mentioned will be clearly understood by those skilled in the art from the description below.

Additional advantages, objects, and features of the disclosure will be set forth in part in the description which follows and in part will become apparent to those having ordinary skill in the art upon examination of the following or may be learned from practice of the disclosure. The objectives and other advantages of the disclosure may be realized and attained by the structure particularly pointed out in the written description and claims hereof as well as the appended drawings.

A display apparatus according to an embodiment of the present disclosure may include a display panel in which a plurality of data lines, a plurality of gate lines, and a plurality of pixels are arranged, a gate driving circuit connected to the plurality of gate lines, and a data driving circuit connected to the plurality of data lines. Each pixel may include a light emitting element, and a first transistor connected to the light emitting element, and a gate electrode of the first transistor and a second electrode of the first transistor may not overlap.

A display apparatus according to another embodiment of the present disclosure may include a display panel in which a plurality of data lines, a plurality of gate lines, and a plurality of pixels are arranged, a gate driving circuit connected to the plurality of gate lines, and a data driving circuit connected to the plurality of data lines. Each pixel may include a light emitting element, a first transistor including a gate electrode and a second electrode connected to the light emitting element, and a shielding layer disposed between the gate electrode and the second electrode of the first transistor.

A display apparatus according to another embodiment of the present disclosure may include a display panel in which a plurality of data lines, a plurality of gate lines, and a plurality of pixels are arranged, a gate driving circuit connected to the plurality of gate lines, and a data driving circuit connected to the plurality of data lines. The plurality of pixels may include a red pixel, a green pixel, and a blue pixel. Each pixel may include a light emitting element including a first electrode and a second electrode, and a capacitance between the first electrode and the second electrode of the red pixel or the green pixel may be greater than a capacitance between the first electrode and the second electrode of the blue pixel.

Specific details of other embodiments are included in the detailed description and drawings.

It is to be understood that both the foregoing general description and the following detailed description of the present disclosure are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this application, illustrate embodiment(s) of the disclosure and together with the description serve to explain the principle of the disclosure. In the drawings:

FIG. 1 is a block diagram showing a display apparatus according to an embodiment of the present disclosure;

FIG. 2 is a cross-sectional view showing the display apparatus according to an embodiment of the present disclosure;

FIG. 3 is a circuit diagram of a pixel included in the display apparatus according to an embodiment of the present disclosure;

FIG. 4 is an exemplary diagram showing display apparatus driving waveforms provided based on the pixel illustrated in FIG. 3 according to an embodiment of the present disclosure;

FIG. 5 is a waveform diagram showing an emission control signal EM of a pixel included in the display apparatus and a driving current of an anode of a light emitting element according to an embodiment of the present disclosure;

FIG. 6A and FIG. 6B are graphs showing a driving current IDS of a driving transistor according to the duty of the emission control signal in the display apparatus according to an embodiment of the present disclosure;

FIG. 7 is a diagram showing a display apparatus according to an embodiment of the present disclosure;

FIG. 8 is a cross-sectional view of the display apparatus according to an embodiment of the present disclosure;

FIG. 9 is a diagram showing a display apparatus according to another embodiment of the present disclosure;

FIG. 10 is a cross-sectional view of the display apparatus according to another embodiment of the present disclosure;

FIG. 11A and FIG. 11B are plan views of a light emitting element in the display apparatus according to another embodiment of the present disclosure; and

FIG. 12A to 12C are cross-sectional views of the light emitting element in the display apparatus according to another embodiment of the present disclosure.

### DETAILED DESCRIPTION

Hereinafter, preferred embodiments of the present disclosure will be described with reference to the attached drawings. Throughout the specification, the same reference numerals refer to substantially the same components.

In the following description, if it is determined that a detailed description of known techniques associated with the present disclosure would unnecessarily obscure the gist of the present disclosure, detailed description thereof will be omitted. In addition, the component names used in the following description are selected in consideration of the ease of writing the specification, and may differ from the names of parts of the actual product.

Shapes, sizes, ratios, angles, numbers, etc. shown in the figures to describe embodiments of the present disclosure are exemplary and thus are not limited to particulars shown in the figures. Like numbers refer to like elements throughout the specification.

It will be further understood that, when the terms “include”, “have” and “comprise” are used in the present disclosure, other parts may be added unless “only” is used. An element described in the singular form is intended to include a plurality of elements unless context clearly indicates otherwise.

In interpretation of a component, the component is interpreted as including an error range unless otherwise explicitly described.

In describing various embodiments of the present disclosure, for example, when describing a positional relationship between two parts using “on”, “above”, “under”, “by”, or the like, one or more other parts may be located between the two parts unless “right” or “directly” is used.

In describing various embodiments of the present disclosure, for example, when describing a temporal chronological relationship between events using “after”, “subsequently to”, “next to”, “before”, or the like, cases where events are not continuous may also be included unless “right” or “directly” is used.

In the following description of various embodiments, “first” and “second” are used to describe various components, but such components are not limited by these terms. The terms are used to discriminate one component from another component. Accordingly, a first component mentioned in the following description may be a second component within the technical spirit of the present disclosure.

The features within various embodiments of the present disclosure may be partially or wholly combined with one another and may be technically capable of various interconnections and operations, and the various embodiments may be implemented independently or may be implemented together in a related relationship.

Hereinafter, a display apparatus according to an embodiment of the present disclosure will be described with reference to the drawings.

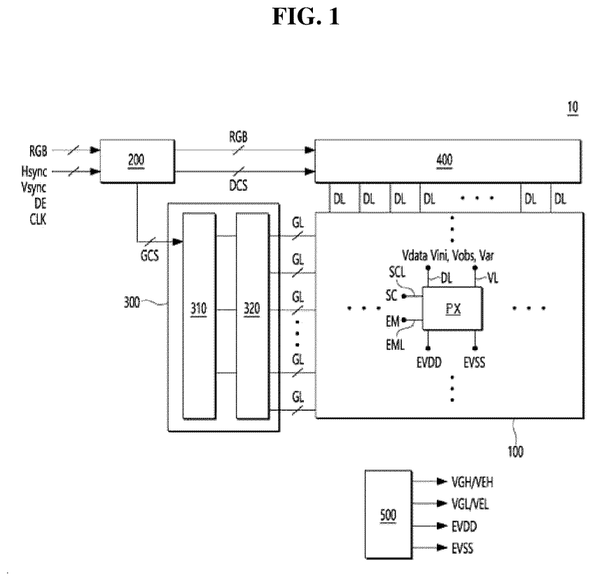

FIG. 1 is a block diagram showing a display apparatus according to an embodiment of the present disclosure.

As shown in FIG. 1, the display apparatus according to an embodiment of the present disclosure may include a panel that displays an image through pixels in which a plurality of gate lines and a plurality of data lines are arranged to intersect each other, and a driving circuit that drives the panel. The driving circuit may include a gate driving circuit and a data driving circuit, the gate driving circuit may drive the plurality of gate lines, and the data driving circuit may supply a data voltage to the plurality of data lines. For example, the display apparatus 10 according to an embodiment of the present disclosure may include a display panel 100, a data driving circuit 400, a gate driving circuit 300, a power supply 500, and a timing controller 200.

A plurality of pixels PX may be disposed on the display panel 100. The plurality of pixels PX may be disposed at regions where a plurality of data lines DL intersects a plurality of gate lines GL. The pixels PX disposed on the same horizontal line may form a single pixel row. The pixels PX disposed in a single pixel row are connected to a single gate line GL, and a single gate line GL may include at least one scan line and at least one emission line. For example, each pixel PX may be connected to one data line DL and at least one scan line and one emission line, but the embodiments of the present disclosure are not limited thereto.

The data driving circuit 400 may be connected to the data lines DL. The data driving circuit 400 may drive the data lines DL. The gate driving circuit 300 may be connected to the gate lines GL. The gate driving circuit 300 may drive the gate lines GL. The power supply 500 may supply power required to operate each of the plurality of pixels PX.

The plurality of pixels PX may be commonly supplied with a high-level driving voltage EVDD and a low-level driving voltage EVSS from the power supply 500. The plurality of pixels PX may be supplied with a bias voltage Vobs and an initialization voltage Var(Vini) through a power line VL.

TFTs constituting the pixels PX may be implemented as oxide TFTs including an oxide semiconductor layer. When considering electron mobility, process deviation, etc., the oxide TFT can be advantageous for large-area display panel 100. The present disclosure is not limited thereto, and the semiconductor layer of the TFT may be formed of amorphous silicon, low-temperature polysilicon, or polysilicon.

Each pixel PX may include a light emitting element (organic light emitting diode (OLED)), a driving TFT that supplies current to the light emitting element, a switching TFT that supplies a data voltage to the driving TFT, and a storage capacitor that holds the data voltage supplied to the driving TFT. The storage capacitor may maintain the data voltage for one frame. Although the light emitting element is described as an OLED in the present disclosure, the light emitting element is not limited to an OLED. The light emitting element may include an organic light emitting element, an inorganic light emitting element, a micro-LED, a mini-LED, and the like, and the embodiments of the present disclosure are not limited thereto.

Each pixel PX may further include a plurality of TFTs and a storage capacitor to compensate for a threshold voltage change in the driving TFT.

A touch unit may be arranged on the display panel 100. The touch unit may include touch sensors. Touch input may be sensed using separate touch sensors or may be sensed through pixels PX. The touch sensors may be arranged on the screen of the display panel in a form of an on-cell type or an add on type or built into the display panel 100 in a form of an in-cell type, but the embodiments of the present disclosure are not limited thereto.

The timing controller 200 may control driving timing of the data driving circuit 400 and the gate driving circuit 300. The timing controller 200 may rearrange digital video data RGB input from the outside such that the digital video data RGB is suitable for the resolution of the display panel 100 and supply the same to the data driving circuit 400.

In addition, the timing controller 200 may generate a data control signal DCS for controlling the operation timing of the data driving circuit 400 and a gate control signal GCS for controlling the operation timing of the gate driving circuit 300 on the basis of timing signals such as a vertical synchronization signal Vsync, a horizontal synchronization signal Hsync, a dot clock signal CLK, and a data enable signal DE.

The timing controller 200 may multiply an input frame frequency by i and control the operation timing of the display panel driver at a frame frequency of the input frame frequency x i (i being a positive integer greater than 0) Hz. The input frame frequency may be 60 Hz in the National Television Standards Committee (NTSC) format and 50 Hz in the Phase-Alternating Line (PAL) format, but the embodiments of the present disclosure are not limited thereto.

The data driving circuit 400 may convert digital video data RGB input from the timing controller 200 into an analog data voltage on the basis of the data control signal DCS and provide the analog data voltage to each data line DL.

The data driving circuit 400 may include one or more source drive ICs SICs. The source drive IC may generate a data voltage by converting digital video data of an input image into an analog gamma compensation voltage under the control of the timing controller 200 and output the data voltage to the data lines DL. The source drive IC may be mounted on a flexible circuit board, for example, in the form of a chip on film (COF) or may be directly bonded onto a substrate of a non-display area of the display panel 100 using a COG process, but the embodiments of the present disclosure are not limited thereto.

COFs may be bonded to a pad area of the display panel 100 and a source PCB through an anisotropic conductive film (ACF). Input pins of the COFs may be electrically connected to output terminals (pads) of the source PCB. Output pins of source COFs may be electrically connected to data pads formed on the substrate of the display panel 100 through an ACF.

For another example, the driver IC may be disposed on the display panel. For example, the driver IC may be disposed in the form of a chip on panel (COP), but the embodiments of the present disclosure are not limited thereto.

Although FIG. 1 illustrates that the data driving circuit 400 is disposed on one side of the display panel 100, the number and placement position of the data driving circuit 400 are not limited thereto. For example, the data driving circuit 400 may be composed of a plurality of integrated circuits (ICs) and disposed on one side of the display panel 100, but the embodiments of the present disclosure are not limited thereto.

The gate driving circuit 300 may generate a scan signal and an emission signal based on the gate control signal GCS. The gate driving circuit 300 may include at least one scan driver 310 and an emission driver 320.

At least one scan driver 310 may generate a scan signal SC in a row-sequential manner and supply the same to the gate lines GL to drive at least one scan line SCL connected to each pixel row. At least one scan driver 310 may output a scan pulse in response to a start pulse and a shift clock from a timing controller 200 and shift the scan pulse in accordance with a shift clock timing.

The emission driver 320 may generate an emission signal EM in a row-sequential manner to drive at least one emission control signal line EML connected to each pixel row and supply the same to emission lines. The emission driver 320 may output an emission control signal pulse in response to a start pulse and a shift clock from the timing controller 200 and sequentially shift the emission control signal pulse in accordance with the shift clock.

The scan signal SC may include a scan pulse that swings between a gate-on voltage VGL and a gate-off voltage VGH. The emission control signal EM may include an emission control signal pulse that swings between a gate-on voltage VEL and a gate-off voltage VEH. The scan pulse may be used to select pixels PX of a line to which a data voltage Vdata will be written. The emission control signal EM may define a light emitting time of the pixels PX.

The gate lines GL may be used to supply the scan signal SC and the emission control signal EM to the plurality of pixels PX, and the data lines DL may be used to supply a data voltage Vdata to the plurality of pixels PX. According to various embodiments, the gate lines GL may include a plurality of scan lines SCL for supplying the scan signal SC and a plurality of emission control signal lines EML for supplying the emission control signal EM.

The gate driving circuit 300 may be formed on the display panel along with the thin film transistors of the pixels. This is called Gate In Panel (GIP).

The power supply 500 may generate DC power required to drive the pixel array of the display panel 100 and the display panel driver using a DC-DC converter. The DC-DC converter may include a charge pump, a regulator, a buck converter, a boost converter, etc., but the embodiments of the present disclosure are not limited thereto.

The power supply 500 may receive a DC input voltage from a host system and generate DC voltages such as the gate-on voltage VGL and VEL, the gate-off voltage VGH and VEH, a high-level driving voltage EVDD, and a low-level driving voltage EVSS.

The gate-on voltage VGL and VEL and the gate-off voltage VGH and VEH may be supplied to a level shifter and the gate driving circuit 300. The high-level driving voltage EVDD and the low-level driving voltage EVSS may be supplied in common to the pixels PX.

The plurality of pixels PX of the display panel 100 may include at least a first pixel, a second pixel, and a third pixel. The first pixel, the second pixel, and the third pixel may emit lights of different colors. For example, the first pixel may be a red pixel, the second pixel may be a green pixel, and the third pixel may be a blue pixel.

The plurality of pixels PX may have the same size or different sizes. The first pixel, the second pixel, and the third pixel may be configured to have different sizes in consideration of the lifespan of the light emitting elements included in the first pixel, the second pixel, and the third pixel, or the color balance, but the embodiments of the present disclosure are not limited thereto.

The display apparatus according to the present disclosure may use the variable refresh rate (VRR) technology for varying the driving frequency in order to achieve low power consumption.

For example, the timing controller 200 may generate signals such that the pixels PX can be driven at various refresh rates. For example, the timing controller 200 may generate signals related to operation such that the pixels PX can be driven in a variable refresh rate (VRR) mode or switchably between a first refresh rate and a second refresh rate. For example, the timing controller 200 may drive the pixels PX at various refresh rates by simply changing the rate of the clock signal, generating a synchronization signal such that a horizontal blank or a vertical blank occurs, or driving the gate driving circuit 300 in a mask manner.

Therefore, operation needs to be performed using an anode reset frame in order to vary the driving frequency, and each pixel may be configured to supply an anode reset voltage Var for operation using the anode reset frame.

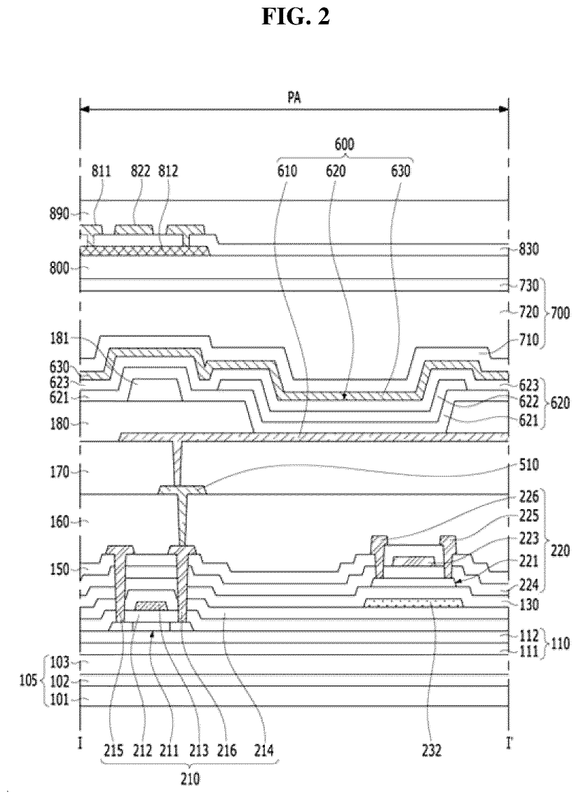

FIG. 2 is a cross-sectional view showing the display apparatus according to an embodiment of the present disclosure.

The display apparatus according to an embodiment of the present disclosure may include a substrate 105. The substrate 105 may include an insulating material. For example, the substrate 105 may include glass or plastic, but the embodiments of the present disclosure are not limited thereto. The substrate 105 may have a multilayer structure, but the embodiments of the present disclosure are not limited thereto. For example, the substrate 105 may have a structure in which a first substrate layer 101, an insulating layer 102, and a second substrate layer 103 are sequentially disposed or laminated, but the embodiments of the present disclosure are not limited thereto. The second substrate layer 103 may include the same material as the first substrate layer 101, but the embodiments of the present disclosure are not limited thereto. For example, the first substrate layer 101 and the second substrate layer 103 may include a polymer material such as polyimide (PI). The insulating layer 102 may include an insulating material. Accordingly, in the display apparatus according to the embodiment of the present disclosure, the substrate 105 may have flexibility. Therefore, in the display apparatus according to the embodiment of the present disclosure, damage to the substrate 105 due to bending stress can be prevented.

The substrate 105 may include a display area, a bending area, and a pad area, but the embodiments of the present disclosure are not limited thereto. The bending area may be located between the display area and the pad area, but the embodiments of the present disclosure are not limited thereto. An image to be provided to a user may be displayed in the display area. For example, the display area may include a plurality of pixel areas PA. Each pixel area PA may express a specific color. For example, a light emitting element 600 may be disposed in each pixel area PA. The light emitting element 600 may emit light representing a specific color. For example, the light emitting element 600 may include a first electrode 610, an emission layer 620, and a second electrode 630 disposed or laminated on the substrate 105.

The first electrode 610 may include a conductive material. The first electrode 610 may be formed of a material having a high reflectivity. For example, the first electrode 610 may include a metal such as aluminum (Al) and silver (Ag), but the embodiments of the present disclosure are not limited thereto. The first electrode 610 may have a multilayer structure, but the embodiments of the present disclosure are not limited thereto. For example, the first electrode 610 may have a structure in which a reflective electrode made of a metal is disposed between transparent electrodes made of a transparent conductive material such as ITO and IZO, but the embodiments of the present disclosure are not limited thereto.

The emission layer 620 can generate light with a brightness corresponding to the voltage difference between the first electrode 610 and the second electrode 630. For example, the emission layer 620 may include an emission material layer (EML) 622 containing an emission material. The emission material may include an organic material, an inorganic material, or a hybrid material, but the embodiments of the present disclosure are not limited thereto. For example, the display apparatus according to the embodiment of the present disclosure may be an OLED display device in which the emission layer 620 includes an emission material layer 622 made of an organic material. Without being limited thereto, the emission layer 620 may include an inorganic emission material. For example, the emission layer 620 may be formed of a material including a quantum dot, a micro-LED, or a mini-LED, but the embodiments of the present disclosure are not limited thereto.

The emission layer 620 may have a multilayer structure, but the embodiments of the present disclosure are not limited thereto. For example, the emission layer 620 may include at least one of a first common layer 621 positioned between the first electrode 610 and the emission material layer 622 and a second common layer 623 positioned between the emission material layer 622 and the second electrode 630. Each of the first common layer 621 and the second common layer 623 may include at least one of a hole injection layer (HIL), a hole transport layer (HTL), a hole blocking layer (HBL), an electron blocking layer (EBL), an electron transport layer (ETL), and an electron injection layer (EIL), but the embodiments of the present disclosure are not limited thereto. For example, in the display apparatus according to the embodiment of the present disclosure, the first common layer 621 may include at least one of the hole injection layer (HIL), the electron blocking layer (EBL), and the hole transport layer (HTL), and the second common layer 623 may include at least one of the electron transport layer (ETL), the hole blocking layer (HBL), and the electron injection layer (EIL), but the embodiments of the present disclosure are not limited thereto.

The second electrode 630 may include a conductive material. The second electrode 630 may include a different material from the first electrode 610, but the embodiments of the present disclosure are not limited thereto. For example, the second electrode 630 may be a transparent electrode made of a transparent conductive material such as ITO and IZO, but the embodiments of the present disclosure are not limited thereto. The second electrode 630 may have higher transmittance than the first electrode 610. Accordingly, in the display apparatus according to the embodiment of the present disclosure, light generated from the emission layer 620 may be emitted through the second electrode 630.

A driving circuit may be disposed in each pixel area PA. The driving circuit may generate a driving current provided to the light emitting element 600. The driving circuit may be electrically connected to signal lines GL, DL, EVDD, and EVSS. For example, each pixel area PA may be configured by signal lines GL, DL, EVDD, and EVSS. The signal lines GL, DL, EVDD, and EVSS may transmit various signals for implementing an image. For example, the signal lines GL, DL, EVDD, and EVSS may include gate lines GL through which a gate signal is applied, data lines DL through which a data signal is applied, and power voltage supply lines EVDD and EVSS through which a power voltage is supplied, but the embodiments of the present disclosure are not limited thereto. The driving circuit may generate a driving current corresponding to a data signal according to a gate signal. The operation of the light emitting element 600 may be maintained for one frame. For example, the driving circuit may include a first thin film transistor 210 and a second thin film transistor 220, but the embodiments of the present disclosure are not limited thereto.

The first thin film transistor 210 may be electrically connected to the light emitting element 600. The first thin film transistor 210 may supply a driving current corresponding to a data signal to the light emitting element 600. For example, the first thin film transistor 210 may be disposed between the light emitting element 600 and one of the power voltage supply lines EVDD and EVSS. The first thin film transistor 210 may include a first semiconductor layer 211, a first gate electrode 213, a first source electrode 215, and a first drain electrode 216.

The first semiconductor layer 211 may be positioned close to the substrate 105. The first semiconductor layer 211 may include a semiconductor material. For example, the first semiconductor layer 211 may include silicon, but the embodiments of the present disclosure are not limited thereto. The first semiconductor layer 211 may include a polycrystalline semiconductor, but the embodiments of the present disclosure are not limited thereto. For example, the first semiconductor layer 211 may include polysilicon or low temperature polysilicon (LTPS), but the embodiments of the present disclosure are not limited thereto. For another example, the first semiconductor layer 211 may include an oxide semiconductor, but the embodiments of the present disclosure are not limited thereto. The first semiconductor layer 211 may include a first source region, a first drain region, and a first channel region. The first channel region may be disposed between the first source region and the first drain region. The first channel region may have lower electrical conductivity than the first source region and the first drain region. For example, the first source region and the first drain region may include a higher content of conductive impurities than the first channel region, but the embodiments of the present disclosure are not limited thereto.

A first insulating film 212 may be disposed on the first semiconductor layer 211. The first insulating film 212 may extend to the outside of the first semiconductor layer 211. For example, the side surface of the first semiconductor layer 211 may be covered by the first insulating film 212. The first insulating film 212 may include an insulating material. For example, the first insulating film 212 may include silicon oxide (SiOx) and/or silicon nitride (SiNx), but the embodiments of the present disclosure are not limited thereto. The silicon oxide (SiOx) may include silicon dioxide (SiO2). The first insulating film 212 may include a material having a high dielectric constant. For example, the first insulating film 212 may include a material such as hafnium oxide (HfO), but the embodiments of the present disclosure are not limited thereto. The first insulating film 212 may be an interlayer insulating film, but the embodiments of the present disclosure are not limited thereto.

The first gate electrode 213 may be disposed on the first insulating film 212. The first gate electrode 213 may include a conductive material. For example, the first gate electrode 213 may include a single layer or multiple layers including one of aluminum (Al), chromium (Cr), copper (Cu), titanium (Ti), molybdenum (Mo), and tungsten (W), or an alloy thereof, but the embodiments of the present disclosure are not limited thereto. The first gate electrode 213 may be insulated from the first semiconductor layer 211 by the first insulating film 212. The first gate electrode 213 may overlap the first channel region of the first semiconductor layer 211. For example, the first channel region of the first semiconductor layer 211 may have an electrical conductivity corresponding to a voltage applied to the first gate electrode 213.

A second insulating film 214 may be disposed on the first gate electrode 213. The second insulating film 214 may extend to the outside of the first gate electrode 213. For example, the side surface of the first gate electrode 213 may be covered by the second insulating film 214. The second insulating film 214 may extend along the first insulating film 212. The second insulating film 214 may include an insulating material. For example, the second insulating film 214 may include silicon oxide (SiOx), but the embodiments of the present disclosure are not limited thereto. The second insulating film 214 may be a gate insulating film, but the embodiments of the present disclosure are not limited thereto.

The first source electrode 215 may be disposed on the second insulating film 214. The first source electrode 215 may be insulated from the first gate electrode 213 by the second insulating film 214. The first source electrode 215 may include a different material from the first gate electrode 213, but the embodiments of the present disclosure are not limited thereto. The first source electrode 215 may include a conductive material. For example, the first source electrode 215 may include a single layer or multiple layers including one of aluminum (Al), chromium (Cr), copper (Cu), titanium (Ti), molybdenum (Mo), and tungsten (W), or an alloy thereof, but the embodiments of the present disclosure are not limited thereto. The first source electrode 215 may be electrically connected to the first source region of the first semiconductor layer 211.

The first drain electrode 216 may be disposed on the second insulating film 214. The first drain electrode 216 may include a conductive material. For example, the first drain electrode 216 may include a single layer or multiple layers including one of aluminum (Al), chromium (Cr), copper (Cu), titanium (Ti), molybdenum (Mo), and tungsten (W) or an alloy thereof, but the embodiments of the present disclosure are not limited thereto. The first drain electrode 216 may be insulated from the first gate electrode 213 by the second insulating film 214. The first drain electrode 216 may include a different material from the first gate electrode 213, but the embodiments of the present disclosure are not limited thereto. For example, the first drain electrode 216 may include the same material as the first source electrode 215, but the embodiments of the present disclosure are not limited thereto. The first drain electrode 216 and the first source electrode 215 may be formed through the same process, but the embodiments of the present disclosure are not limited thereto. The first drain electrode 216 may be electrically connected to the first drain region of the first semiconductor layer 211. The first drain electrode 216 may be spaced apart from the first source electrode 215.

The second thin film transistor 220 may be electrically connected to the first thin film transistor 210. The second thin film transistor 220 may transmit a data signal to the first gate electrode 213 of the first thin film transistor 210 according to a scan signal. For example, the second thin film transistor 220 may be disposed between a data line DL and the first gate electrode 213 of the first thin film transistor 210. The structure of the second thin film transistor 220 may be the same as the structure of the first thin film transistor 210, but the embodiments of the present disclosure are not limited thereto. For example, the second thin film transistor 220 may include a second semiconductor layer 221, a second gate electrode 223, a second source electrode 225, and a second drain electrode 226.

The second semiconductor layer 221 may include a semiconductor material. The second semiconductor layer 221 may include the same material as the first semiconductor layer 211 or a different material from the first semiconductor layer 211. For example, the second semiconductor layer 221 may be an oxide semiconductor such as IGZO, but the embodiments of the present disclosure are not limited thereto. For another example, the second semiconductor layer 221 may include polysilicon or low temperature polysilicon (LTPS), but the embodiments of the present disclosure are not limited thereto.

The second semiconductor layer 221 may be disposed on a different layer from the first semiconductor layer 211, but the embodiments of the present disclosure are not limited thereto. For example, a first protective film 130 may be positioned on the second insulating film 214, and the second semiconductor layer 221 may be disposed on the first protective film 130. The first protective film 130 may include silicon oxide (SiOx) or silicon nitride (SiNx), but the embodiments of the present disclosure are not limited thereto. Accordingly, in the display apparatus according to the embodiments of the present disclosure, damage to the second semiconductor layer 221 due to the formation process of the first semiconductor layer 211 can be prevented.

The second semiconductor layer 221 may include a second source region, a second drain region, and a second channel region. The second channel region may be disposed between the second source region and the second drain region. The second source region and the second drain region may have lower resistance than the second channel region, but the embodiments of the present disclosure are not limited thereto. For example, the second source region and the second drain region may include a conductive region of an oxide semiconductor. The second channel region may be a non-conductive region of the oxide semiconductor.

A fourth insulating film 224 may be disposed on the second semiconductor layer 221. The fourth insulating film 224 may include an insulating material. The fourth insulating film 224 may include the same material as the first insulating film 212, but the embodiments of the present disclosure are not limited thereto. For example, the fourth insulating film 224 may have a multilayer structure, but the embodiments of the present disclosure are not limited thereto.

The second gate electrode 223 may be disposed on the fourth insulating film 224. For example, the second gate electrode 223 may overlap the second channel region of the second semiconductor layer 221. The second gate electrode 223 may include a conductive material. For example, the second gate electrode 223 may include a single layer or multiple layers including one of aluminum (Al), chromium (Cr), copper (Cu), titanium (Ti), molybdenum (Mo), and tungsten (W), or an alloy thereof, but the embodiments of the present disclosure are not limited thereto. The second gate electrode 223 may include the same material as the first gate electrode 213, but the embodiments of the present disclosure are not limited thereto. The second gate electrode 223 may be insulated from the second semiconductor layer 221 by the fourth insulating film 224. For example, the second channel region of the second semiconductor layer 221 may have an electrical conductivity corresponding to a voltage applied to the second gate electrode 223.

A second protective film 150 may be disposed on the fourth insulating film 224. The second protective film 150 may include silicon oxide (SiOx) or silicon nitride (SiNx), but the embodiments of the present disclosure are not limited thereto.

The second source electrode 225 may be disposed on the second protective film 150. The second source electrode 225 may include a conductive material. For example, the second source electrode 225 may include one of aluminum (Al), chromium (Cr), copper (Cu), titanium (Ti), molybdenum (Mo), and tungsten (W), or an alloy thereof, but the embodiments of the present disclosure are not limited thereto. The second source electrode 225 may include the same material as the first source electrode 215, but the embodiments of the present disclosure are not limited thereto. The second source electrode 225 may be insulated from the second gate electrode 223 by the fourth insulating film 224.

The second source electrode 225 may include a different material from the second gate electrode 223, but the embodiments of the present disclosure are not limited thereto. The second source electrode 225 may be electrically connected to the second source region of the second semiconductor layer 221. For example, the fourth insulating film 224 and the second protective film 150 may include a second source contact hole that partially exposes the second source region of the second semiconductor layer 221. The second source electrode 225 may include a region overlapping the second source region of the second semiconductor layer 221. For example, the second source electrode 225 may be in contact with the second source region of the second semiconductor layer 221 within the second source contact hole.

The second drain electrode 226 may be disposed on the second protective film 150. The second drain electrode 226 may include a conductive material. For example, the second drain electrode 226 may include a single layer or double layer including one of aluminum (Al), chromium (Cr), copper (Cu), titanium (Ti), molybdenum (Mo), and tungsten (W), or an alloy thereof, but the embodiments of the present disclosure are not limited thereto. The second drain electrode 226 may include the same material as the first drain electrode 216, but the embodiments of the present disclosure are not limited thereto. The second drain electrode 226 may be insulated from the second gate electrode 223 by the fourth insulating film 224. The second drain electrode 226 may include a different material from the second gate electrode 223, but the embodiments of the present disclosure are not limited thereto. For example, the second drain electrode 226 may include the same material as the second source electrode 225, but the embodiments of the present disclosure are not limited thereto. The second drain electrode 226 and the second source electrode 225 may be formed through the same process, but the embodiments of the present disclosure are not limited thereto. The second drain electrode 226 may be electrically connected to the second drain region of the second semiconductor layer 221. The second drain electrode 226 may be spaced apart from the second source electrode 225. For example, the fourth insulating film 224 and the second protective film 150 may include a second drain contact hole that partially exposes the second drain region of the second semiconductor layer 221. The second drain electrode 226 may include a region overlapping the second drain region of the second semiconductor layer 221. For example, the second drain electrode 226 may be in contact with the second drain region of the second semiconductor layer 221 within the second drain contact hole.

The second thin film transistor 220 may further include an auxiliary layer 232 under the second semiconductor layer 221. The auxiliary layer 232 may overlap the second semiconductor layer 221. For example, the auxiliary layer 232 may include a single layer or multiple layers including one of aluminum (Al), chromium (Cr), copper (Cu), titanium (Ti), molybdenum (Mo), nickel (Ni), neodymium (Nd), and tungsten (W) or an alloy thereof, but the embodiments of the present disclosure are not limited thereto. The auxiliary layer 232 may prevent or at least reduce light from reaching the second semiconductor layer 221, thereby extending the lifespan of the second thin film transistor 220. For example, the auxiliary layer 232 may be a light-shielding layer, but the embodiments of the present disclosure are not limited thereto. For example, another auxiliary layer may be formed under the first thin film transistor 210. Another auxiliary layer may be disposed on a buffer layer 112. When another auxiliary layer is formed, an insulating film may be further formed on the buffer layer 112. The other auxiliary layer may be formed of the same material as the auxiliary layer 232, but the embodiments of the present disclosure are not limited thereto. Since the other auxiliary layer can prevent light from reaching the first semiconductor layer 211, the lifespan of the first thin film transistor 210 can be extended.

A buffer film 110 may be disposed between the substrate 105 and the driving circuit of each pixel area PA. The buffer film 110 can prevent or at least reduce contamination by the substrate 105 during a driving circuit formation process. For example, the buffer film 110 may be disposed on the substrate 105. For example, the buffer film 110 may cover the display area of the substrate 105. For example, the buffer film 110 may completely cover the display area of the substrate 105. The buffer film 110 may be disposed between the substrate 105 and the first semiconductor layer 211 of each pixel area PA. The buffer film 110 may include an insulating material. For example, the buffer film 110 may include an inorganic insulating material such as silicon oxide (SiOx) and silicon nitride (SiNx), but the embodiments of the present disclosure are not limited thereto. The buffer film 110 may have a multilayer structure, but the embodiments of the present disclosure are not limited thereto. For example, the buffer film 110 may have a laminated structure of a first buffer layer 111 and a second buffer layer 112 including a different material from the first buffer layer 111, but the embodiments of the present disclosure are not limited thereto.

The first protective film 130 can prevent or at least reduce damage to the first thin film transistor 210 due to external impact and moisture. The first protective film 130 may extend between the auxiliary layer 230 and the second semiconductor layer 221 of each pixel area PA. Accordingly, in the display apparatus according to the embodiment of the present disclosure, damage to the first thin film transistors 210 due to external impact and moisture can be effectively prevented.

The second protective film 150 may be disposed between the fourth insulating film 224 and the second source electrode 225 and between the fourth insulating film 224 and the second drain electrode 226 in each pixel area PA. The second protective film 150 may prevent damage to the second semiconductor layer 221 due to external impact and moisture. For example, the second protective film 150 may extend to the outside of the second semiconductor layer 221 along the fourth insulating film 224. The second protective film 150 may include a different material from the fourth insulating film 224, but the embodiments of the present disclosure are not limited thereto. For example, the fourth protective film 150 may include silicon nitride (SiNx), but the embodiments of the present disclosure are not limited thereto. Accordingly, in the display apparatus according to the embodiment of the present disclosure, damage to the second semiconductor layer 221 due to external impact and moisture can be effectively prevented.

The first source electrode 215 of the first thin film transistor may be disposed on the second protective film 150 of each pixel area PA. The first source electrode 215 may include a conductive material. For example, the first source electrode 215 may include a single layer or multiple layers including one of aluminum (Al), chromium (Cr), copper (Cu), titanium (Ti), molybdenum (Mo), and tungsten (W), or an alloy thereof, but the embodiments of the present disclosure are not limited thereto. The first source electrode 215 may include a different material from the first gate electrode 213, but the embodiments of the present disclosure are not limited thereto. The first source electrode 215 may be electrically connected to the first source area of the first semiconductor layer 211. For example, the first insulating film 212, the second insulating film 214, the first protective film 130, the fourth insulating film 224, and the second protective film 150 may include a first contact hole that partially exposes the first source region of the first semiconductor layer 211 of the first thin film transistor 210. The first source electrode 215 may include a region that overlaps the first source region of the first semiconductor layer 211. For example, the first source electrode 215 may be in contact with the first source region of the first semiconductor layer 211 within the first contact hole.

The first drain electrode 216 of the first thin film transistor may be disposed on the second protective film 150 of each pixel area PA. The first drain electrode 216 may include a conductive material. For example, the first drain electrode 216 may include a single layer or multiple layers including one of aluminum (Al), chromium (Cr), copper (Cu), titanium (Ti), molybdenum (Mo), and tungsten (W), or an alloy thereof, but the embodiments of the present disclosure are not limited thereto. The first drain electrode 216 may include a different material from the first gate electrode 213, but the embodiments of the present disclosure are not limited thereto. For example, the first drain electrode 216 may include the same material as the first source electrode 215, but the embodiments of the present disclosure are not limited thereto. The first drain electrode 216 and the first source electrode 215 may be formed through the same process, but the embodiments of the present disclosure are not limited thereto. The first drain electrode 216 may be electrically connected to the first drain region of the first semiconductor layer 211. The first drain electrode 216 may be spaced apart from the first source electrode 215. For example, the first insulating film 212, the second insulating film 214, the first protective film 130, the fourth insulating film 224, and the second protective film 150 may include a first contact hole that partially exposes the first drain region of the first semiconductor layer 211. The first drain electrode 216 may include a region overlapping the first drain region of the first semiconductor layer 211. For example, the first drain electrode 216 may be in contact with the first drain region of the first semiconductor layer 211 within the first contact hole.

The light emitting element 600 of each pixel area PA may be disposed on the transistors of each pixel area PA. For example, the first thin film transistor 210 and the second thin film transistor 220 of each pixel area PA may be disposed between the substrate 105 and the first electrode 610 of each pixel area PA. Accordingly, in the display apparatus according to the embodiment of the present disclosure, the area occupied by each pixel area PA can be minimized. Therefore, the resolution of the display apparatus according to the embodiment of the present disclosure can be improved.

A first planarization layer 160 and a second planarization layer 170 may be disposed between the driving circuit and the light emitting element 600 of each pixel area PA. For example, the first electrode 610, the emission layer 620, and the second electrode 630 of each pixel area PA may be disposed on the second planarization layer 170 of each pixel area PA. The first planarization layer 160 and the second planarization layer 170 can reduce or eliminate steps caused by the transistors. For example, the upper surface of the second planarization layer 170 facing the light emitting element 600 of each pixel area PA may be a flat surface. The first planarization layer 160 and the second planarization layer 170 may include an insulating material. For example, the first planarization layer 160 and the second planarization layer 170 may include an organic insulating material, but the embodiments of the present disclosure are not limited thereto. The second planarization layer 170 may include a material different from the first planarization layer 160, but the embodiments of the present disclosure are not limited thereto. Accordingly, in the display apparatus according to the embodiment of the present disclosure, steps caused by the transistors can be effectively reduced or eliminated. For another example, one of the first planarization layer 160 and the second planarization layer 170 may be omitted.

An intermediate electrode 510 may be disposed between the first planarization layer 160 and the second planarization layer 170 of each pixel area PA. The light emitting element 600 may be electrically connected to the first drain electrode 216 of the first thin film transistor 210 through the intermediate electrode 510. For example, the intermediate electrode 510 may penetrate the first planarization layer 160 and be connected to the first drain electrode 216, and the first electrode 610 of the light emitting element 600 may penetrate the second planarization layer 170 and be connected to the intermediate electrode 510. The intermediate electrode 510 may include a region overlapping the first drain electrode 216 and a region overlapping the first electrode 610. For example, the intermediate electrode 510 may be disposed between the first drain electrode 216 and the first electrode 610. The intermediate electrode 510 may be in contact with the first drain electrode 216. For example, the intermediate electrode 510 may be in direct contact with the first drain electrode 216. The first electrode 610 may be in contact with the intermediate electrode 510. For example, the first electrode 610 may be in direct contact with the intermediate electrode 510. The intermediate electrode 510 may include a conductive material. For example, the intermediate electrode 510 may include a metal such as aluminum (Al), chromium (Cr), copper (Cu), titanium (Ti), molybdenum (Mo), and tungsten (W), but the embodiments of the present disclosure are not limited thereto. The intermediate electrode 510 may include a different material from the first drain electrode 216 and the first electrode 610, but the embodiments of the present disclosure are not limited thereto.

A bank 180 may be arranged on the second planarization layer 170 of each pixel area PA. The bank 180 may include an insulating material. For example, the bank 180 may be formed of a material including a black pigment or the like, or an organic material such as a benzocyclobutene resin, a polyimide resin, an acrylic resin, or a photosensitive polymer, but the embodiments of the present disclosure are not limited thereto. When the bank 180 is formed of a material including a black pigment or a black dye, the bank 180 may be a black bank. When the bank 180 is formed of a material including a black pigment or a black dye, light from the outside can be blocked, and the brightness of the display apparatus can be further improved. The bank 180 may include a material different from the first planarization layer 160 and the second planarization layer 170, but the embodiments of the present disclosure are not limited thereto. The bank 180 may cover the edge of the first electrode 610. The emission layer 620 and the second electrode 630 of each pixel area PA may be disposed on a portion of the first electrode 610 exposed by the bank 180. For example, the bank 180 may define an emission area within each pixel area PA.

A spacer 181 may be disposed on the bank 180 of each pixel area PA. The spacer 181 may be formed with a width narrower than the width of the bank 180. The spacer 181 may include an insulating material. For example, the spacer 181 may include an organic insulating material, but the embodiments of the present disclosure are not limited thereto. The spacer 181 may be formed of the same material as the bank 180, but the embodiments of the present disclosure are not limited thereto. The spacer 181 can prevent damage to the emission material layer 622 formed on the bank 180 and an adjacent pixel area PA due to a fine metal mask.

The emission layer 620 of each pixel area PA may extend over the bank 180 and the spacer 181. Each pixel area PA may exhibit a different color from the color of an adjacent pixel area PA. For example, the emission material layer 622 of each pixel area PA may be separated from the emission material layer 622 of an adjacent pixel area PA. The emission material layer 622 of each pixel area PA may include end portions positioned within each pixel area PA. The emission material layer 622 may be formed using a fine metal mask FMM, but the embodiments of the present disclosure are not limited thereto. The end portions of each emission material layer 622 may be disposed on the bank 180 and the spacer 181. The first common layer 621 and the second common layer 623 of each emission layer 620 may extend along the surface of the bank 180. For example, the first common layer 621 and the second common layer 623 of each pixel area PA may be connected to the first common layer 621 and the second common layer 623 of an adjacent pixel area PA. Accordingly, the process efficiency of the display apparatus according to the embodiment of the present disclosure can be improved.

A voltage supplied to the second electrode 630 of each pixel area PA may be the same as the voltage supplied to the second electrode 630 of an adjacent pixel area PA. For example, the second electrode 630 of each pixel area PA may be connected to the second electrode 630 of a pixel area PA adjacent to the bank 180. Accordingly, the display apparatus according to the embodiment of the present disclosure can control the brightness of each pixel area PA through a gate signal and a data signal applied to each pixel area PA. The second electrode 630 of each pixel area PA may be in contact with the second electrode 630 of an adjacent pixel area PA.

A sealing member 700 may be arranged on the light emitting element 600 of each pixel area PA. The sealing member 700 can prevent or at least reduce damage to the light emitting element 600 due to external impact and moisture. The sealing member 700 may have a multilayer structure, but the embodiments of the present disclosure are not limited thereto. For example, the sealing member 700 may include a first sealing layer 710, a second sealing layer 720, and a third sealing layer 730, but the embodiments of the present disclosure are not limited thereto. The first sealing layer 710, the second sealing layer 720, and the third sealing layer 730 may include an insulating material. The second sealing layer 720 may include a different material from the first sealing layer 710 and the third sealing layer 730, but the embodiments of the present disclosure are not limited thereto.

For example, the first sealing layer 710 and the third sealing layer 730 may include an inorganic insulating material, and the second sealing layer 720 may include an organic insulating material, but the embodiments of the present disclosure are not limited thereto. Accordingly, in the display apparatus according to the embodiment of the present disclosure, damage to the light emitting elements 600 due to external impact and moisture can be effectively prevented or at least reduced. Steps caused by the light emitting element 600 of each pixel area PA can be removed by the sealing member 700. For example, the upper surface of the sealing member 700 facing the substrate 105 may be a flat plane.

A touch part may be arranged on the sealing member 700. The touch part may detect a touch of a user and/or a tool. For example, the touch part may include touch electrodes 811 and 822 and bridge electrodes 812. The touch electrodes 811 and 822 may be arranged side by side. The bridge electrodes 812 may connect the touch electrodes 811. The touch electrodes 811 and 822 and the bridge electrodes 812 may include a conductive material. For example, the touch electrodes 811 and 822 and the bridge electrodes 812 may include a single layer or double layer including one of aluminum (Al), chromium (Cr), copper (Cu), titanium (Ti), molybdenum (Mo), and tungsten (W), or an alloy thereof, but the embodiments of the present disclosure are not limited thereto. The touch electrodes 811 and 822 and the bridge electrodes 812 may overlap the display area of the substrate 105. The light emitting element 600 of each pixel area PA may be disposed outside the touch electrodes 811 and 822 and the bridge electrodes 812. For example, the touch electrodes 811 and 822 and the bridge electrodes 812 may overlap the bank 180. The touch electrodes 811 and 822 and the bridge electrodes 812 may be spaced apart from the light emitting element 600 of each pixel area PA. Accordingly, in the display apparatus according to the embodiment of the present disclosure, light emitted from each light emitting element 600 in a direction perpendicular to the upper surface of the substrate 105 may not be blocked by the touch electrodes 811 and 822 and the bridge electrode 812. Therefore, in the display apparatus according to the embodiment of the present disclosure, a decrease in the brightness of each pixel area PA due to the touch electrodes 811 and 822 and the bridge electrodes 812 can be prevented.

An insulating film 830 may be disposed between the bridge electrodes 812 and the touch electrodes 811 and 822. The insulating film 830 may include an insulating material. For example, the insulating film 830 may include a material such as silicon oxide (SiOx) and silicon nitride (SiNx), but the embodiments of the present disclosure are not limited thereto. The second touch electrodes 822 may be disposed on the same layer as the first touch electrodes 811, but the embodiments of the present disclosure are not limited thereto. For example, the touch electrodes 811 and 822 and the bridge electrodes connecting the touch electrodes 822 may be disposed on the insulating film 830. The insulating film 830 may include touch contact holes that partially expose the bridge electrodes 812. The touch electrode 811 may be connected to the bridge electrode 812 corresponding thereto through one of the touch contact holes.

A buffer film 800 may be disposed between the sealing member 700 and the touch part 811, 812, and 822. The buffer film 800 can prevent damage to the sealing member 700 and the light emitting elements 600 due to the forming process of the touch electrodes 811 and 822 and the bridge electrodes 812. The buffer film 800 may include an insulating material. For example, the buffer film 800 may include a material such as silicon oxide (SiOx) and silicon nitride (SiNx), but the embodiments of the present disclosure are not limited thereto.

An insulating film 890 may be disposed on the touch part 811, 812, and 822. The insulating film 890 can prevent or at least reduce damage to the touch part 811, 812, and 822 due to external impact and moisture.

The display apparatus according to the present disclosure described with reference to FIG. 1 and FIG. 2 may use Variable Refresh Rate (VRR) technology to achieve low power consumption. The display apparatus may be operated by varying a frequency using the VRR technology.

For example, the display apparatus may be operated at 120 Hz and then at 60 Hz. When the display apparatus is operated at a variable frequency, visibility needs to be reduced when the frequency is varied. Therefore, an intermediate frequency (80 Hz, 48 Hz, or the like) may be introduced to reduce visibility during operation at 120 Hz and then at 60 Hz.

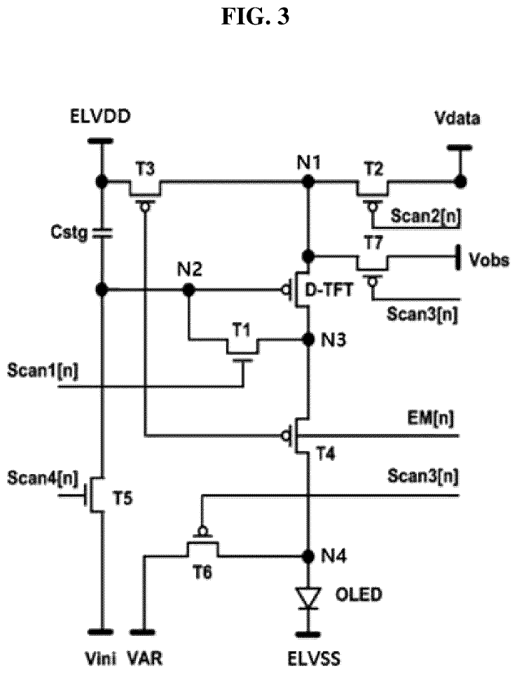

In order to use an intermediate frequency, operation needs to be performed with an anode reset frame. For example, the anode reset frame may be set to 4 ms (Scan3 (see FIG. 3) 240 Hz), but the embodiments of the present disclosure are not limited thereto.

As described with reference to FIG. 1, the gate driving circuit 300 may include at least one scan driver 310 and the emission driver 320. At least one scan driver 310 may generate a scan signal SC in a row-sequential manner to drive at least one scan line SCL connected to each pixel row and supply the scan signal to the gate lines GL. The emission driver 320 may generate an emission signal EM in a row-sequential manner to drive at least one emission control signal line EML connected to each pixel row and supply the emission signal to the emission control signal lines. The gate driving circuit 300 may be arranged on one side or both sides of the display panel 100 in a GIP structure, but the embodiments of the present disclosure are not limited thereto.

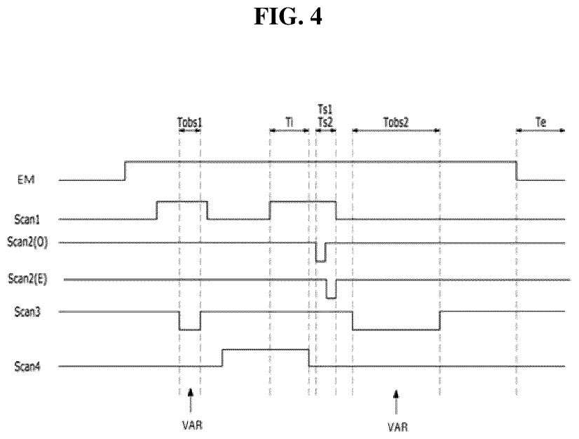

FIG. 3 is a circuit diagram of a pixel included in the display apparatus according to an embodiment of the present disclosure. FIG. 4 is an exemplary diagram showing driving waveforms of the display apparatus provided on the basis of the pixel illustrated in FIG. 3.

Each pixel PX may include a pixel driving circuit and an emission part, as illustrated in FIG. 3.

The pixel driving circuit may include a first transistor T1 to a seventh transistor T7, a storage capacitor Cstg, and a driving transistor D-TFT. The emission part may include a light emitting element, but the embodiments of the present disclosure are not limited thereto. Although the reference symbol of the light emitting element is OLED, the light emitting element is not limited to an organic light emitting diode. For example, the light emitting element may include an inorganic light emitting element, an organic light emitting element, a quantum dot light emitting element, a micro-LED element, or a mini-LED element, but the embodiments of the present disclosure are not limited thereto.

The first transistor T1 to the seventh transistor T7 and the driving transistor D-TFT may be configured as different types of transistors. For example, one of the first transistor T1 to the seventh transistor T7 and the driving transistor D-TFT may be a transistor having an oxide semiconductor as an active layer. Since the oxide semiconductor has a low off-current, it may be suitable for a switching transistor having a short turn-on time and a long turn-off time.

For another example, another one of the first transistor T1 to the seventh transistor T7 and the driving transistor D-TFT may be a transistor having a polysilicon or low temperature polysilicon (LTPS) semiconductor layer as an active layer. Polysilicon has high mobility, low power consumption, and high reliability, and thus may be suitable for the driving transistor D-TFT. The active layer may be a semiconductor layer, but is not limited thereto.

The first transistor T1 to the seventh transistor T7 and the driving transistor D-TFT may be an N-type transistor or a P-type transistor. In the N-type transistor, the carrier is an electron, and thus electrons can flow from the source electrode to the drain electrode and current can flow from the drain electrode to the source electrode. In the P-type transistor, the carrier is a hole, and thus holes can flow from the source electrode to the drain electrode and current can flow from the source electrode to the drain electrode. For example, one of the first transistor T1 to the seventh transistor T7 and the driving transistor D-TFT may be an N-type transistor, and another one of the first transistor T1 to the seventh transistor T7 and the driving transistor D-TFT may be a P-type transistor. For example, one of the first transistor T1 to the seventh transistor T7 and the driving transistor D-TFT may be configured as one of an N-type transistor and a P-type transistor or a combination thereof. For example, one of the first transistor T1 to the seventh transistor T7 and the driving transistor D-TFT may be configured as one of an oxide transistor and a low-temperature polysilicon transistor or a combination thereof.

The pixel driving circuit may include the driving transistor D-TFT, the first transistor T1 to the seventh transistor T7, and the storage capacitor Cstg, but the embodiments of the present disclosure are not limited thereto.

The driving transistor D-TFT may include a first node N1, a second node N2, and a third node N3. In the driving transistor D-TFT, the second node N2 may be a gate node, the first node N1 may be a source node or a drain node, and the third node N3 may be a drain node or a source node. Hereinafter, for convenience of description, an example in which the second node N2 is a gate node, the first node N1 is a source node, and the third node N3 is a drain node in the driving transistor D-TFT will be described, but the embodiments of the present disclosure are not limited thereto.

A gate electrode of the driving transistor D-TFT may be connected to the second node N2, and a first electrode of the driving transistor D-TFT may be connected to the first node N1. A second electrode of the driving transistor D-TFT may be connected to the third node N3. The driving transistor D-TFT may be controlled according to the voltage of the second node N2 to control the current flowing through the light emitting element OLED. The driving transistor D-TFT may be connected between the first node N1 and the third node N3.

The first transistor T1 may be connected between the second node N2 and the third node N3. The first transistor T1 may be controlled by a first scan signal Scan1(n) to switch between the second node N2 and the third node N3.

The second transistor T2 may be connected to the first node N1. The second transistor T2 may be controlled by a second scan signal Scan2(n) to apply a data voltage Vdata to the first node N1. The second transistor T2 may be connected between the first node N1 and a data voltage line.

The third transistor T3 may be connected to the first node N1. The third transistor T3 may be controlled by the emission control signal EM (n) to apply a high-level driving voltage ELVDD supplied through a high-level driving voltage line to the first node N1. The third transistor T3 may be connected between the first node N1 and the high-level driving voltage line.

The fourth transistor T4 may be connected between the third node N3 and the fourth node N4. The fourth transistor T4 may be controlled by the emission control signal EM (n) to switch between the third node N3 and the fourth node N4.

The fifth transistor T5 may be connected to the second node N2. The fifth transistor T5 may be controlled by a fourth scan signal Scan4(n) to apply an initialization voltage Vini to the second node N2. The fifth transistor T5 may be connected between the second node N2 and an initialization voltage line.

The sixth transistor T6 may be connected to the fourth node N4. The sixth transistor T6 may be controlled by a third scan signal Scan3(n) to apply an anode reset voltage VAR to the fourth node N4. The sixth transistor T6 may be connected between the fourth node N4 and a reset voltage line or an anode reset voltage line.

The seventh transistor T7 may be connected to the first node N1. The seventh transistor T7 may be controlled by the third scan signal Scan3(n) to apply a bias voltage Vobs to the first node N1. The bias voltage Vobs can improve the hysteresis of the driving transistor D-TFT by controlling the gate-source voltage Vgs flowing through the driving transistor D-TFT. For example, the threshold voltage Vth of the driving transistor D-TFT may be changed by applying the bias voltage Vobs. The seventh transistor T7 may be connected between the first node N1 and a bias voltage line.

The storage capacitor Cstg may be connected between the high-level driving voltage terminal for supplying the high-level driving voltage ELVDD and the second node N2. The storage capacitor Cstg can store the data voltage Vdata. For example, the storage capacitor Cstg may store the data voltage Vdata for one frame.

The light emitting element OLED may include an anode and a cathode. The anode of the light emitting element OLED may be connected to the fourth node N4. The cathode of the light emitting element OLED may be connected to a low-level driving voltage line through which a low-level driving voltage ELVSS is supplied.

The light emitting element OLED may include any one of an organic emission layer, an inorganic emission layer, and a quantum dot emission layer, or may include a laminated or mixed structure of an organic emission layer (or an inorganic emission layer) and a quantum dot emission layer, but the embodiments of the present disclosure are not limited thereto. For example, the light emitting element may be an organic light emitting element including an anode, an organic layer, and a cathode. Other examples include light emitting elements such as micro-LEDs (light emitting diodes), mini-LEDs, and quantum dot light emitting diodes (QLEDs) containing quantum dots (QDs).

The light emitting element OLED may output light corresponding to one of various colors such as red, green, and blue, or may output white light, but the embodiments of the present disclosure are not limited thereto.

As shown in FIG. 3 and FIG. 4, the display apparatus according to the embodiment of the present disclosure may operate in the order of a first bias period Tobs1, an initialization period Ti, a first sampling period Ts1, a second sampling period Ts2, and a second bias period Tobs2 during a refresh period, but the embodiments of the present disclosure are not limited thereto.

FIG. 3 shows a case in which an odd-numbered pixel and an even-numbered pixel share an odd-numbered scan driver and an even-numbered scan driver included in at least one scan driver 310, but the embodiments of the present disclosure are not limited thereto. Accordingly, the second scan signal Scan2 may include a second odd-numbered scan signal Scan2(O) and a second even-numbered scan signal Scan2(E).

The first bias period Tobs1 may be a period in which a bias voltage is applied to the first electrode (or the first node N1) of the driving transistor D-TFT. During the first bias period Tobs1, the emission control signal EM, the first scan signal Scan1, the second odd-numbered scan signal Scan2(O), and the second even-numbered scan signal Scan2(E) may be applied as a high voltage, and the third scan signal Scan3 and the fourth scan signal Scan4 may be applied as a low voltage. The anode reset voltage VAR may be applied during the first bias period Tobs1.

The initialization period Ti may be a period in which the gate electrode of the driving transistor D-TFT is initialized. During the initialization period Ti, the emission control signal EM, the first scan signal Scan1, the second odd-numbered scan signal Scan2(O), the second even-numbered scan signal Scan2(E), the third scan signal Scan3, and the fourth scan signal Scan4 may be applied as a high voltage.

The first sampling period Ts1 and the second sampling period Ts2 may be periods for sampling the threshold voltage of the driving transistor D-TFT included in odd-numbered sub-pixels and even-numbered sub-pixels. During the first sampling period Ts1, the emission control signal EM, the first scan signal Scan1, the second even-numbered scan signal Scan2(E), and the third scan signal Scan3 may be applied as a high voltage, and the second odd-numbered scan signal Scan2(O) and the fourth scan signal Scan4 may be applied as a low voltage. During the second sampling period Ts2, the emission control signal EM, the first scan signal Scan1, the second odd-numbered scan signal Scan2(O), and the third scan signal Scan3 may be applied as a high voltage, and the second even-numbered scan signal Scan2(E) and the fourth scan signal Scan4 may be applied as a low voltage.

The second bias period Tobs2 may be a period in which the bias voltage is applied to the first electrode (or the first node) of the driving transistor D-TFT. During the second bias period Tobs2, the emission control signal EM, the second odd-numbered scan signal Scan2(O), and the second even-numbered scan signal Scan2(E) may be applied as a high voltage, and the first scan signal Scan1, the third scan signal Scan3, and the fourth scan signal Scan4 may be applied as a low voltage. During the second bias period Tobs2, the anode reset voltage VAR may be applied.

The display apparatus according to the embodiment of the present disclosure may have an emission period Te after the refresh period ends. During the emission period Te, the first scan signal Scan1, the fourth scan signal Scan4, and the emission control signal EM may be applied as a low voltage, and the second odd-numbered scan signal Scan2(O), the second even-numbered scan signal Scan2(E), and the third scan signal Scan3 may be applied as a high voltage.

During the emission period Te, the light emitting element OLED can emit light according to the high-level driving voltage ELVDD supplied to the anode of the light emitting element OLED since the third and fourth transistors T3 and T4 are turned on by the turn-on signal (low voltage) of the emission control signal EM. In addition, since the third and fourth transistors T3, T4 are turned off by the turn-off signal (high voltage) of the emission control signal EM, the anode voltage of the light emitting element OLED decreases, and thus the light emitting element OLED is also turned off (does not emit light).

Recently, light emitting display apparatuses have been used as mobile display apparatuses. In order to reduce power consumption, light emitting display apparatuses for mobile devices are continuously increasing the emission efficacy of light emitting elements, and accordingly, the required current for the same brightness emission is gradually decreasing. As the required current decreases, the light emitting elements become more sensitive to anode voltage variations.

The factor for charging or boosting the anode (the fourth node N4 in FIG. 3) of the light emitting element can be distinguished by a coupling component of the driving current of the driving transistor (D-TFT in FIG. 3) and the emission control signal.

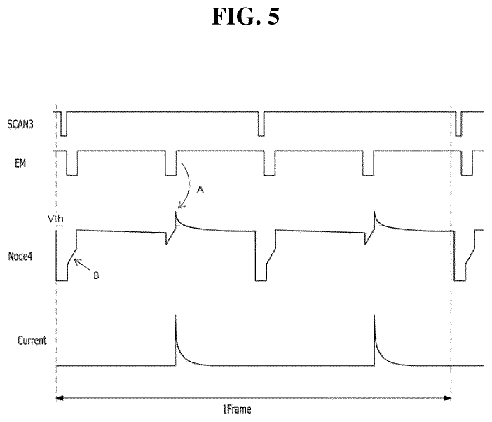

FIG. 5 is a waveform diagram showing the emission control signal EM for the pixels and the driving current of the anode of the light emitting element in the display apparatus according to the embodiment of the present disclosure.

In the pixel circuit diagram described in FIG. 3, a parasitic capacitance may occur between the emission control signal (EM) line and the fourth node N4, and each pixel can control brightness by varying the data voltage to change the driving current of the driving transistor D-TFT.

When the emission control signal EM is at a low level, the fourth transistor T4 in FIG. 3 is turned on, and thus the driving transistor D-TFT can provide the driving current B to the anode (fourth node N4 (Node4)) of the light emitting element OLED. When transition of the emission control signal EM from a low level to a high level occurs, the fourth transistor T4 in FIG. 3 is turned off, and thus the anode (the fourth node N4 (Node4)) of the light emitting element OLED can be in a floating state. At this time, since transition of the emission control signal EM from a low level to a high level occurs, coupling can occur between the anode (the fourth node N4 (Node4)) of the light emitting element OLED and the emission control signal (EM) line (refer to “A” in FIG. 5). The voltage of the anode (the fourth node N4 (Node4)) of the light emitting element OLED may increase due to coupling between the anode (the fourth node N4 (Node4)) of the light emitting element OLED and the emission control signal (EM) line.

In case of very low grayscale operation, the duty of the emission control signal EM may be controlled to significantly decrease. For example, in case of very low grayscale operation, the on time (low level) of the emission control signal EM can be relatively very small. Further, as the duty (on time) of the emission control signal and the luminance decrease, coupling A between the anode (the fourth node N4 (Node4)) of the light emitting element OLED and the emission control signal (EM) line can contribute more to increase in the voltage of the anode (the fourth node N4 (Node4)) of the light emitting element (OLED). In FIG. 5, the threshold voltage Vth of the light emitting element is indicated by a tangent line, and the current is the current of the light emitting element OLED.

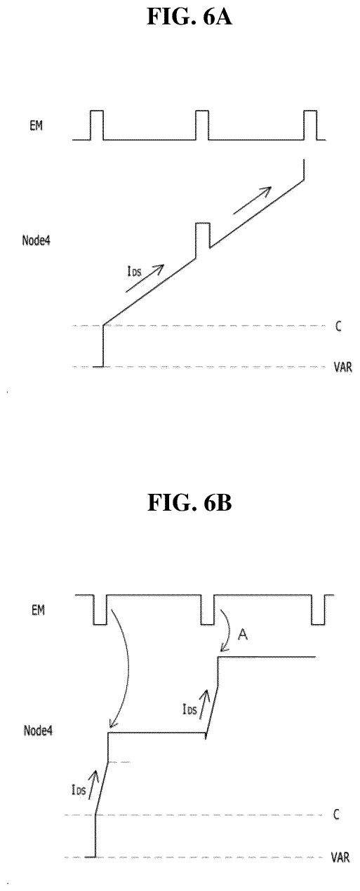

FIG. 6A and FIG. 6B are comparative graphs of the driving current of the driving transistor according to the duty of the emission control signal in the display apparatus according to the embodiment of the present disclosure. FIG. 6A is a graph showing the driving current IDS of the driving transistor when the duty (on time) of the emission control signal is relatively high. FIG. 6B is a graph showing the driving current IDS of the driving transistor when the duty (on time) of the emission control signal is relatively low.

Referring to FIG. 6A and FIG. 6B, it can be ascertained that coupling A between the anode (the fourth node N4 (Node4)) of the light emitting element and the emission control signal (EM) line can contribute more to increase in the voltage of the anode (the fourth node N4 (Node4)) of the light emitting element when the duty of the emission control signal EM is relatively low compared to when the duty of the emission control signal EM is relatively high. For example, the voltage of the anode (the fourth node N4 (Node4)) of the light emitting element can increase by “C” due to charge sharing.

Therefore, in order to improve the image quality at low grayscales, a voltage variation ΔV in the anode (the fourth node N4 (Node4)) of the light emitting element may be determined by the following mathematical expression 1.

$$Δ V = ( VGH - VGL ) \times \frac{{C}_{EM - Node 4}}{{C}_{EM - Node 4} + {C}_{OLED}} \qquad [ Mathematical expression 1 ]$$

Here, VGH is the gate high voltage, VGL is the gate low voltage, CEM-Node4 is the capacitance between the emission control signal line and the anode (the fourth node N4 (Node4)) of the light emitting element, and COLED is the capacitance between the anode and the cathode of the light emitting element.

As can be ascertained from Mathematical expression 1, by reducing the capacitance between the emission control signal (EM) line and the anode (the fourth node N4 (Node4)) of the light emitting element or increasing the capacitance between the anode and the cathode of the light emitting element, the voltage variation ΔV in the anode (the fourth node N4 (Node4)) of the light emitting element OLED can be reduced.

Therefore, the display apparatus according to the embodiment of the present disclosure can reduce the voltage variation ΔV in the anode (the fourth node N4 (Node4)) of the light emitting element by reducing the capacitance between the emission control signal (EM) line and the anode (the fourth node N4 (Node4)) of the light emitting element, or by increasing the capacitance between the anode and the cathode of the light emitting element.

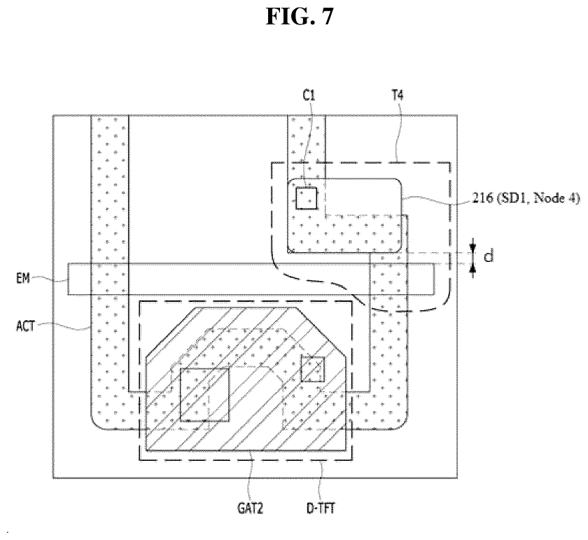

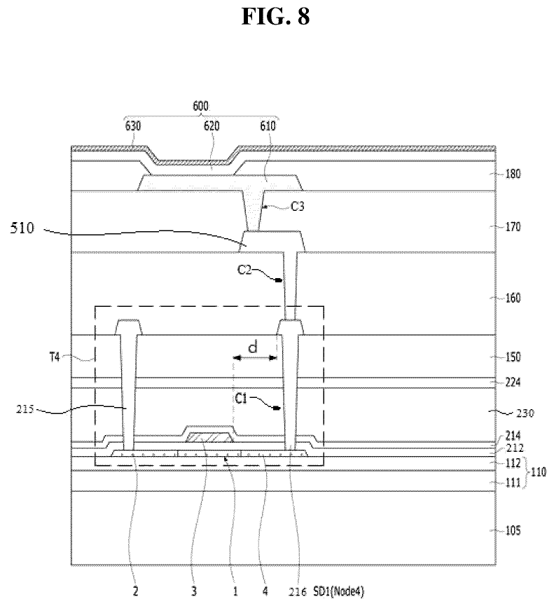

FIG. 7 is a diagram showing the display apparatus according to an embodiment of the present disclosure. FIG. 8 is a cross-sectional view of the display apparatus according to an embodiment of the present disclosure.

As illustrated in FIG. 3, the fourth transistor T4 may be connected between the driving transistor D-TFT and the anode of the light emitting element. The fourth transistor T4 may be controlled by the emission control signal EM (n) to switch between the driving transistor D-TFT and the anode of the light emitting element. For example, the fourth transistor T4 may be referred to as a light emitting transistor, but the embodiments of the present disclosure are not limited thereto.

As illustrated in FIG. 7 and FIG. 8, if the gate electrode (e.g., emission control signal line) of the fourth transistor T4 and the drain electrode N4 of the fourth transistor T4 are spaced further apart (d), the capacitance between the emission control signal (EM) line and the anode (fourth node N4 (Node4)) of the light emitting element can be reduced.

The display apparatus according to an embodiment of the present disclosure may be designed such that the gate electrode (emission control signal line) of the fourth transistor T4 and the drain electrode N4 of the fourth transistor T4 do not overlap.

As illustrated in FIG. 8, the buffer film 110 including the first buffer layer 111 and the second buffer layer 112 may be formed on the substrate 105. The fourth transistor T4 may be disposed on the buffer film 110.

The fourth transistor T4 may include a semiconductor layer 1, a gate electrode 3, a source electrode 215, and a drain electrode 216.

The semiconductor layer 1 may be formed on the buffer film 110. The semiconductor layer 1 may include silicon, but the embodiments of the present disclosure are not limited thereto. The semiconductor layer 1 may include a polycrystalline semiconductor, but the embodiments of the present disclosure are not limited thereto. For example, the semiconductor layer 1 may include polysilicon or low temperature polysilicon (LTPS), but the embodiments of the present disclosure are not limited thereto. For another example, the semiconductor layer 1 may include an oxide semiconductor.

The semiconductor layer 1 may include a source region 2, a drain region 4, and a channel region. The channel region may be disposed between the source region 2 and the drain region 4. The channel region may have lower electrical conductivity than the source region 2 and the drain region 4. For example, the source region 2 and the drain region 4 may include a higher content of conductive impurities than the channel region, but the embodiments of the present disclosure are not limited thereto.

The first insulating film 212 may be disposed on the semiconductor layer 1. The first insulating film 212 may extend to the outside of the semiconductor layer 1. For example, the side surface of the semiconductor layer 1 may be covered by the first insulating film 212. The first insulating film 212 may include an insulating material. For example, the first insulating film 212 may include silicon oxide (SiOx) and/or silicon nitride (SiNx), but the embodiments of the present disclosure are not limited thereto. The silicon oxide (SiOx) may include silicon dioxide (SiO2). The first insulating film 212 may include a material having a high dielectric constant. For example, the first insulating film 212 may include a material such as hafnium oxide (HfO), but the embodiments of the present disclosure are not limited thereto.

The gate electrode 3 may be disposed on the first insulating film 212. The gate electrode 3 may include a conductive material. For example, the gate electrode 3 may include a single layer or multiple layers including one of aluminum (Al), chromium (Cr), copper (Cu), titanium (Ti), molybdenum (Mo), and tungsten (W), or an alloy thereof, but the embodiments of the present disclosure are not limited thereto. The gate electrode 3 may be insulated from the semiconductor layer 1 by the first insulating film 212. The gate electrode 3 may overlap the channel region of the semiconductor layer 1. For example, the channel region of the semiconductor layer 1 may have an electrical conductivity corresponding to a voltage applied to the gate electrode 3.

The second insulating film 214 may be disposed on the gate electrode 3. The second insulating film 214 may extend to the outside of the gate electrode 3. For example, the side surface of the gate electrode 3 may be covered by the second insulating film 214. The second insulating film 214 may extend along the first insulating film 212. The second insulating film 214 may include an insulating material. For example, the second insulating film 214 may include silicon oxide (SiOx), but the embodiments of the present disclosure are not limited thereto.

A buffer film 230 may be disposed on the second insulating film 214. The buffer film 230 may include an organic insulating material, but the embodiments of the present disclosure are not limited thereto. The buffer film 230 may be a planarizing film, but the embodiments of the present disclosure are not limited thereto.

A third insulating film 224 and a protective film 150 may be disposed on the buffer film 230. The third insulating film 224 may include an insulating material. The third insulating film 224 may include the same material as the second insulating film 214, but the embodiments of the present disclosure are not limited thereto. For example, the third insulating film 224 may have a multilayer structure, but the embodiments of the present disclosure are not limited thereto. The protective film 150 may include an organic material, but the embodiments of the present disclosure are not limited thereto.

The source electrode 215 may be disposed on the protective film 150. The source electrode 215 may be insulated from the gate electrode 3. The source electrode 215 may include a different material from the gate electrode 3, but the embodiments of the present disclosure are not limited thereto. The source electrode 215 may include a conductive material. For example, the source electrode 215 may include a single layer or multiple layers including one of aluminum (Al), chromium (Cr), copper (Cu), titanium (Ti), molybdenum (Mo), and tungsten (W), or an alloy thereof, but the embodiments of the present disclosure are not limited thereto. The source electrode 215 may be electrically connected to the source region 2 of the semiconductor layer 1.

The drain electrode 216 may be disposed on the protective film 150. The drain electrode 216 may include a conductive material. For example, the drain electrode 216 may include a single layer or multiple layers including one of aluminum (Al), chromium (Cr), copper (Cu), titanium (Ti), molybdenum (Mo), and tungsten (W) or an alloy thereof, but the embodiments of the present disclosure are not limited thereto. The drain electrode 216 may be insulated from the gate electrode 3. The drain electrode 216 may include a different material from the gate electrode 3, but the embodiments of the present disclosure are not limited thereto. For example, the drain electrode 216 may include the same material as the source electrode 215, but the embodiments of the present disclosure are not limited thereto. The drain electrode 216 and the source electrode 215 may be formed through the same process, but the embodiments of the present disclosure are not limited thereto. The drain electrode 216 may be electrically connected to the drain region 4 of the semiconductor layer 1. The drain electrode 216 may be spaced apart from the source electrode 215.

A first contact hole C1 may be formed in the first insulating film 212, the second insulating film 214, the buffer film 230, the third insulating film 224, and the protective film 150 such that the source region 2 and the drain region 4 are exposed. The source electrode 215 and the drain electrode 216 may be electrically connected to the source region 2 and the drain region 4, respectively, through the first contact hole C1.

The first planarization layer 160 and the second planarization layer 170 may be disposed on the drain electrode 216 and the source electrode 215. The light emitting element 600 including the first electrode 610, the emission layer 620, and the second electrode 630 may be disposed on the second planarization layer 170 of the pixel area PA. The first planarization layer 160 and the second planarization layer 170 may reduce or eliminate steps caused by transistors. For example, the upper surface of the second planarization layer 170 facing the light emitting element 600 of each pixel area PA may be a flat surface. The first planarization layer 160 and the second planarization layer 170 may include an insulating material. For example, the first planarization layer 160 and the second planarization layer 170 may include an organic insulating material, but the embodiments of the present disclosure are not limited thereto. The second planarization layer 170 may include a different material from the first planarization layer 160, but the embodiments of the present disclosure are not limited thereto. Accordingly, in the display apparatus according to the embodiment of the present disclosure, steps caused by the transistors can be effectively reduced or eliminated.

The intermediate electrode 510 may be arranged between the first planarization layer 160 and the second planarization layer 170 of each pixel area PA. The light emitting element 600 may be electrically connected to the drain electrode 216 of the fourth transistor T4 through the intermediate electrode 510. For example, the intermediate electrode 510 may be connected to the drain electrode 216 through a second contact hole C2 penetrating the first planarization layer 160, and the first electrode 610 of the light emitting element 600 may be connected to the intermediate electrode 510 through a third contact hole C3 penetrating the second planarization layer 170. The intermediate electrode 510 may include a region overlapping the drain electrode 216 and a region overlapping the first electrode 610. For example, the intermediate electrode 510 may be disposed between the drain electrode 216 and the first electrode 610. The intermediate electrode 510 may include a conductive material. For example, the intermediate electrode 510 may include a metal such as aluminum (Al), chromium (Cr), copper (Cu), titanium (Ti), molybdenum (Mo), and tungsten (W), but the embodiments of the present disclosure are not limited thereto. The intermediate electrode 510 may include a material different from the drain electrode 216 and the first electrode 610, but the embodiments of the present disclosure are not limited thereto.

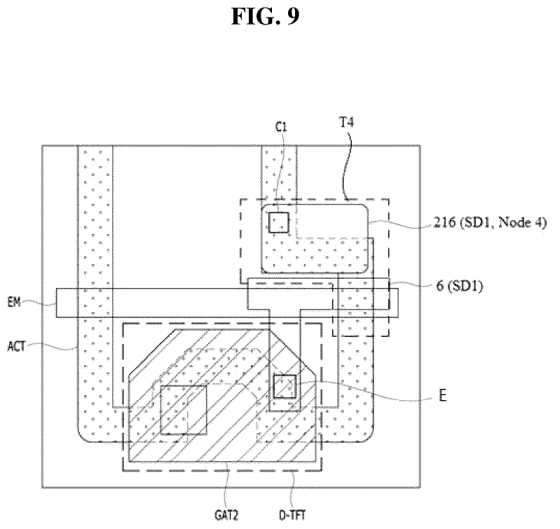

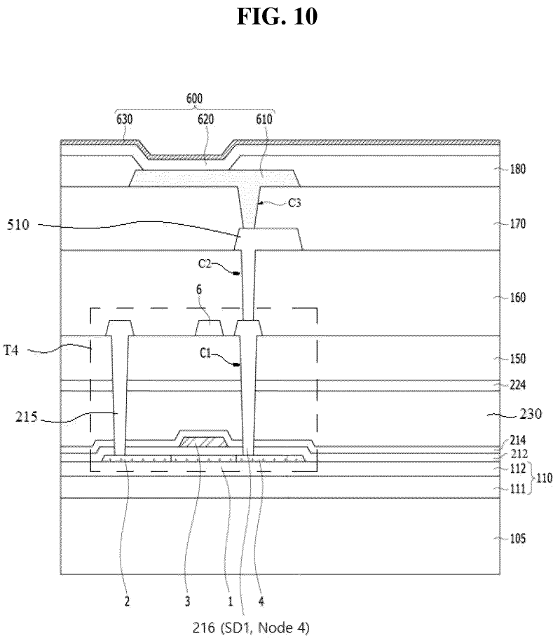

FIG. 9 is a diagram showing a display apparatus according to another embodiment of the present disclosure. FIG. 10 is a cross-sectional view of the display apparatus according to another embodiment of the present disclosure.

As shown in FIG. 9 and FIG. 10, a shielding layer 6 may be formed on the gate electrode (emission control signal line) of the fourth transistor T4 between the gate electrode (emission control signal line) of the fourth transistor T4 and the drain electrode 216 of the fourth transistor T4 using the same material as the drain electrode 216 of the fourth transistor T4. As a result, the capacitance between the emission control signal (EM) line and the anode (fourth node N4) of the light emitting element can be reduced.

The cross-sectional structure shown in FIG. 10 is substantially the same as that shown in FIG. 8. Referring to FIG. 10, the shielding layer 6 may be disposed on the protective film 150 between the drain electrode 216 and the gate electrode 3 of the fourth transistor T4. The shielding layer 6 may be formed of the same material as the source electrode 215 and the drain electrode 216 of the fourth transistor T4, but the embodiments of the present disclosure are not limited thereto.

The high-level driving voltage ELVDD may be supplied to the shielding layer 6, but the embodiments of the present disclosure are not limited thereto. The low-level driving voltage ELVSS may be supplied to the shielding layer 6, and the shielding layer 6 may be floated, but the embodiments of the present disclosure are not limited thereto. For example, the shielding layer 6 may be electrically connected through a contact hole E of the high-level driving voltage supply line.

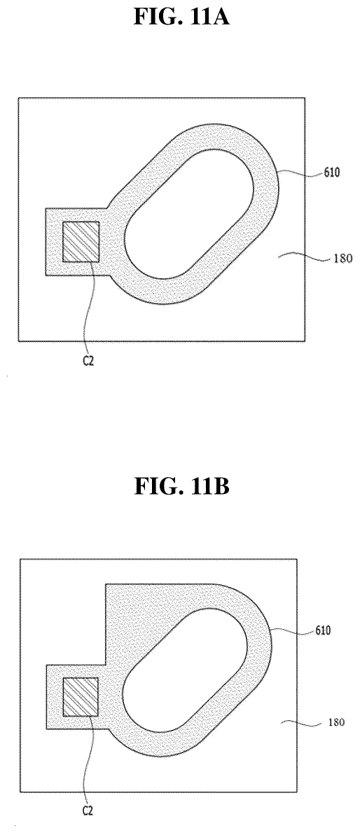

FIG. 11A and FIG. 11B are plan views of light emitting elements in the display apparatus according to another embodiment of the present disclosure. FIG. 11A is a plan view of a blue light emitting element of a blue pixel according to one embodiment. FIG. 11B is a plan view of a red or green light emitting element of a red or green pixel according to one embodiment.

As described with reference to FIG. 1, the plurality of pixels PX of the display panel 100 may include at least a first pixel (red pixel), a second pixel (green pixel), and a third pixel (blue pixel). In addition, the plurality of pixels PX may be configured such that the first pixel, the second pixel, and the third pixel have different sizes in consideration of the lifespan of the light emitting element included in each pixel, color balance, etc. For example, the blue light emitting element of the third pixel (blue pixel) may have a relatively short lifespan. Therefore, the size of the third pixel (blue pixel) may be larger than the size of the first pixel (red pixel) or the second pixel (green pixel), but the embodiments of the present disclosure are not limited thereto.

In addition, the sizes of the first pixel (red pixel), the second pixel (green pixel), and the third pixel (blue pixel) may be the same and the emission area of the third pixel (blue pixel) may be larger than the emission area of the first pixel (red pixel) or the second pixel (green pixel), but the embodiments of the present disclosure are not limited thereto. In addition, the light emitting element 600 of each pixel may include the first electrode 610, the emission layer 620, and the second electrode 630 laminated on the substrate 105, as illustrated in FIG. 2. The bank 180 may cover the edge of the first electrode 610. The emission layer 620 and the second electrode 630 of each pixel area PA may be disposed on a portion of the first electrode 610 exposed by the bank 180. For example, the bank 180 may define an emission area within each pixel area PA.

For example, the bank 180 may be disposed on the first electrode 610 with an opening that exposes the center of the first electrode 610 while covering the edge of the first electrode 610. Therefore, the emission area of each pixel may correspond to the opening of the bank 180.

As illustrated in FIG. 11A and FIG. 11B, the size of the first electrode 610 of the light emitting element of the first pixel (red pixel) or the second pixel (green pixel) may be larger than the size of the first electrode 610 of the blue light emitting element of the third pixel (blue pixel).

Therefore, the capacitance between the first electrode 610 and the second electrode 630 of the light emitting element of the first pixel (red pixel) or the second pixel (green pixel) may be greater than the capacitance between the first electrode 610 and the second electrode 630 of the light emitting element of the third pixel (blue pixel).

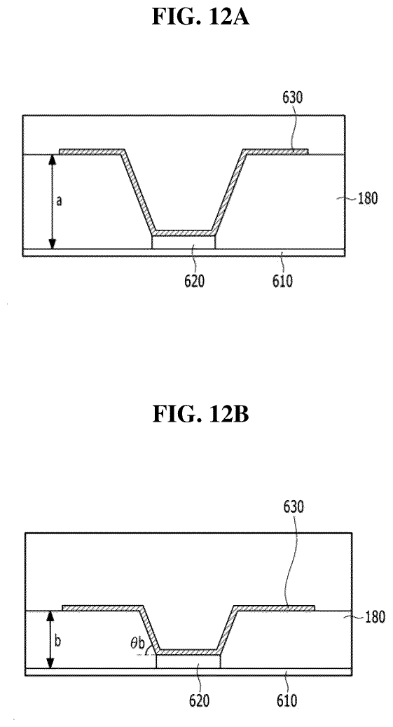

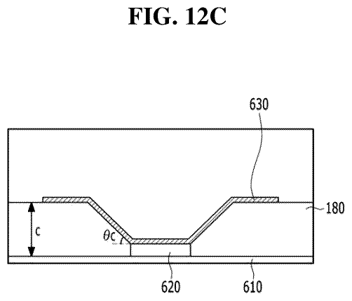

FIG. 12A to FIG. 12C are cross-sectional views of light emitting elements in the display apparatus according to another embodiment of the present disclosure. FIG. 12A is a cross-sectional view of a light emitting element of a blue pixel according to one embodiment. FIG. 12B is a cross-sectional view of a light emitting element of a red pixel or a green pixel according to one embodiment. FIG. 12C is a cross-sectional view of another embodiment of a light emitting element of a red pixel or a green pixel according to one embodiment.

As shown in FIG. 12A, the bank 180 between the first electrode 610 and the second electrode 630 of the light emitting element of the blue pixel may have a thickness of “a”. The bank 180 between the first electrode 610 and the second electrode 630 of the light emitting element of the red pixel or the green pixel may have a thickness of “b”. “a” may be greater than “b”. Accordingly, the thickness b of the bank 180 between the first electrode 610 and the second electrode 630 of the light emitting element of the red pixel or green pixel may be less than the thickness a of the bank 180 between the first electrode 610 and the second electrode 630 of the light emitting element of the blue pixel.

Accordingly, the capacitance between the first electrode 610 and the second electrode 630 of the light emitting element of the first pixel (red pixel) or the second pixel (green pixel) can be greater than the capacitance between the first electrode 610 and the second electrode 630 of the light emitting element of the third pixel (blue pixel).

In addition, referring to FIG. 12A, FIG. 12B and FIG. 12C, the thickness b or c of the bank 180 between the first electrode 610 and the second electrode 630 of the light emitting element of the red pixel or the green pixel is less than the thickness a of the bank 180 between the first electrode 610 and the second electrode 630 of the light emitting element of the blue pixel, and, as shown in FIG. 12C, the inclination angle θc of an inclined surface of the bank 180 is smaller (smaller than the inclination angle θb of an inclined surface of the bank 180 as shown in FIG. 12B), and may be smaller than the inclination angle of an inclined surface of the bank 180 of the third pixel (blue pixel) as shown in FIG. 12A, and thus the capacitance between the first electrode 610 and the second electrode 630 of the light emitting element of the first pixel (red pixel) or the second pixel (green pixel) can be greater than the capacitance between the first electrode 610 and the second electrode 630 of the light emitting element of the third pixel (blue pixel).

According to the present disclosure, the voltage variation ΔV in the anode (the fourth node N4) of the light emitting element can be reduced by reducing the capacitance between the emission control signal (EM) line and the anode (the fourth node N4) of the light emitting element, or by increasing the capacitance between the anode and the cathode of the light emitting element.

According to the present disclosure, the voltage variation in the anode (the fourth node N4) of the light emitting element can be reduced and coupling between the emission control signal (EM) line and the anode (the fourth node N4) of the light emitting element can be reduced, thereby improving low-grayscale image quality.

According to the present disclosure, low-grayscale image quality can be improved, and thus the defect rate of the display apparatus can be reduced. Accordingly, the production energy for producing the display apparatus can be reduced, and the emission of greenhouse gases that may be generated due to the manufacturing process can be reduced, thereby achieving ESG (Environmental/Social/Governance) goals.

The display apparatus according to various embodiments of the present disclosure can be applied to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an electronic book, a portable multimedia player (PMP), a personal digital assistant (PDA), an MP3 player, a mobile medical device, a desktop computer, a laptop computer, a netbook computer, a workstation, a navigation system, a vehicle navigation system, a vehicle display device, a vehicle device, a theater device, a theater display device, a television, a wallpaper device, a signage device, a gaming device, a monitor, a camera, a camcorder, home appliances, etc. The display apparatus according to various embodiments of the present disclosure can be applied to organic light emitting lighting devices and inorganic light emitting lighting devices.

A display apparatus according to various embodiments of the present disclosure may be described as follows.

A display apparatus according to various embodiments of the present disclosure may include a display panel in which a plurality of data lines, a plurality of gate lines, and a plurality of pixels are arranged, a gate driving circuit connected to the plurality of gate lines, and a data driving circuit connected to the plurality of data lines. Each pixel may include a light emitting element and a first transistor connected to the light emitting element, and a gate electrode of the first transistor and a second electrode of the first transistor may not overlap.

A display apparatus according to another embodiment of the present disclosure may include a display panel in which a plurality of data lines, a plurality of gate lines, and a plurality of pixels are arranged, a gate driving circuit connected to the plurality of gate lines, and a data driving circuit connected to the plurality of data lines. Each pixel may include a light emitting element, a first transistor including a gate electrode and a second electrode connected to the light emitting element, and a shielding layer disposed between the gate electrode and the second electrode of the first transistor.

According to the present disclosure, the shielding layer may be disposed on the same layer as the second electrode of the first transistor.

According to the present disclosure, the shielding layer may be formed of the same material as the second electrode of the first transistor.

According to the present disclosure, a high-level driving voltage or a low-level driving voltage may be supplied to the shielding layer.

According to the present disclosure, the shielding layer may be floated.

A display apparatus according to another embodiment of the present disclosure may include a display panel in which a plurality of data lines, a plurality of gate lines, and a plurality of pixels are arranged, a gate driving circuit connected to the plurality of gate lines, and a data driving circuit connected to the plurality of data lines. The plurality of pixels may include a red pixel, a green pixel, and a blue pixel. Each pixel may include a light emitting element including a first electrode and a second electrode, and a capacitance between the first electrode and the second electrode of the red pixel or the green pixel may be greater than a capacitance between the first electrode and the second electrode of the blue pixel.

According to the present disclosure, the size of the first electrode of the red pixel or the green pixel may be greater than the size of the first electrode of the blue pixel.

According to the present disclosure, the thickness of a first bank disposed between the first electrode and the second electrode of the red pixel or the green pixel may be less than the thickness of a second bank disposed between the first electrode and the second electrode of the blue pixel.

According to the present disclosure, the first bank and the second bank have inclined surfaces, and the inclination angle of the inclined surface of the first bank may be less than the inclination angle of the inclined surface of the second bank.

According to the present disclosure, the display apparatus may further include a first transistor connected to the light emitting element, and a second transistor connected to the first transistor. One of the first transistor and the second transistor may include one of an oxide semiconductor layer and a low-temperature polysilicon semiconductor layer.

According to the present disclosure, the display apparatus may further include a second transistor connected to the first transistor. One of the first transistor and the second transistor may include one of an oxide semiconductor layer and a low-temperature polysilicon semiconductor layer.

According to the present disclosure, the display apparatus may further include a sealing member disposed on the light emitting element and a touch part disposed on the sealing member.

According to the present disclosure, voltage variation in the anode of the light emitting element can be reduced by decreasing the capacitance between the emission control signal line and the anode of the light emitting element or by increasing the capacitance between the anode and the cathode of the light emitting element.

According to the present disclosure, the voltage variation ΔV in the anode (the fourth node N4) of the light emitting element OLED can be reduced, and thus coupling between the emission control signal line and the anode (the fourth node N4) of the light emitting element OLED can be reduced, thereby improving low-grayscale image quality.

According to the present disclosure, since the low-grayscale image quality can be improved, the defect rate of the display apparatus can be reduced. Therefore, the production energy for producing the display apparatus can be reduced, and the emission of greenhouse gases that may be generated due to the manufacturing process can be reduced, and thus ESG (Environmental/Social/Governance) goals can be achieved.

It will be apparent to those skilled in the art that various modifications and variations can be made in the present disclosure without departing from the spirit or scope of the disclosure. Thus, it is intended that the present disclosure cover the modifications and variations of this disclosure provided they come within the scope of the appended claims and their equivalents.

What is claimed is:

1. A display apparatus comprising:
a display panel including a plurality of data lines, a plurality of gate lines, and a plurality of pixels;
a gate driving circuit connected to the plurality of gate lines; and
a data driving circuit connected to the plurality of data lines,
wherein each of the plurality of pixels comprises:
a light emitting element; and
a first transistor connected to the light emitting element,
wherein a gate electrode of the first transistor and a second electrode of the first transistor are non-overlapping.

2. A display apparatus comprising:
a display panel including a plurality of data lines, a plurality of gate lines, and a plurality of pixels;
a gate driving circuit connected to the plurality of gate lines; and
a data driving circuit connected to the plurality of data lines,
wherein each of the plurality of pixels comprises:
a light emitting element,
a first transistor including a gate electrode and a second electrode connected to the light emitting element; and
a shielding layer between the gate electrode and the second electrode of the first transistor.

3. The display apparatus of claim 2, wherein the shielding layer is on a same layer as the second electrode of the first transistor.

4. The display apparatus of claim 2, wherein the shielding layer includes a same material as the second electrode of the first transistor.

5. The display apparatus of claim 2, wherein a high-level driving voltage or a low-level driving voltage is supplied to the shielding layer.

6. The display apparatus of claim 2, wherein the shielding layer is floated.

7. The display apparatus of claim 2, further comprising:
a second transistor connected to the first transistor,
wherein one of the first transistor and the second transistor includes one of an oxide semiconductor layer and a low-temperature polysilicon semiconductor layer.

8. The display apparatus of claim 7, wherein the second transistor includes a gate electrode, a first electrode, a semiconductor layer, a second electrode, and an auxiliary layer under the semiconductor layer of the second transistor, and the display apparatus further comprises:
an insulating film on the semiconductor layer of the second transistor, the gate electrode being on the insulating film; and
a protective film on the insulating film,
wherein the auxiliary layer overlaps the semiconductor layer of the second transistor, and
wherein the protective film is between the insulating film and the first electrode of the second transistor and between the insulating film and the second electrode of the second transistor.

9. The display apparatus of claim 2, further comprising:
a bank covering an edge of a first electrode of the light emitting element,
wherein the plurality of pixels includes a red pixel, a green pixel, and a blue pixel, and
wherein a thickness of the bank disposed between a first electrode and a second electrode of the light emitting element of the red pixel or the green pixel is less than a thickness of the bank disposed between a first electrode and a second electrode of the light emitting element of the blue pixel.

10. The display apparatus of claim 9, wherein a size of the first electrode of the light emitting element of the red pixel or the green pixel is greater than a size of the first electrode of the light emitting element of the blue pixel.

11. The display apparatus of claim 2, further comprising:
a sealing member on the light emitting element; and
a touch part disposed on the sealing member.

12. A display apparatus comprising:
a display panel including a plurality of data lines, a plurality of gate lines, and a plurality of pixels;
a gate driving circuit connected to the plurality of gate lines; and
a data driving circuit connected to the plurality of data lines,
wherein the plurality of pixels include a red pixel, a green pixel, and a blue pixel,
wherein each of the plurality of pixels includes a light emitting element including a first electrode and a second electrode, and a capacitance between the first electrode and the second electrode of the red pixel or the green pixel is greater than a capacitance between the first electrode and the second electrode of the blue pixel.

13. The display apparatus of claim 12, wherein a size of the first electrode of the red pixel or the green pixel is greater than a size of the first electrode of the blue pixel.

14. The display apparatus of claim 12, wherein a thickness of a first bank disposed between the first electrode and the second electrode of the red pixel or the green pixel is less than a thickness of a second bank disposed between the first electrode and the second electrode of the blue pixel.

15. The display apparatus of claim 14, wherein the first bank and the second bank have inclined surfaces and an inclination angle of an inclined surface of the first bank is less than an inclination angle of an inclined surface of the second bank.

16. The display apparatus of claim 12, further comprising:
a first transistor including a gate electrode and a second electrode connected to the light emitting element; and
a second transistor connected to the first transistor, the second transistor including a gate electrode, a first electrode, a semiconductor layer, and a second electrode,
wherein a gate electrode of the first transistor and a second electrode of the first transistor are non-overlapping, and
the display apparatus further comprises:
an insulating film on the semiconductor layer of the second transistor, the gate electrode on the insulating film; and
a protective film on the insulating film.

17. The display apparatus of claim 16, wherein the second transistor further includes an auxiliary layer under the semiconductor layer of the second transistor, the auxiliary layer overlapping the semiconductor layer of the second transistor.

18. The display apparatus of claim 16, wherein the protective film is between the insulating film and the first electrode of the second transistor and between the insulating film and the second electrode of the second transistor.

19. The display apparatus of claim 16, wherein each of the plurality of pixels further comprises:
a shielding layer between the gate electrode and the second electrode of the first transistor.
